(19) United States
(12) Patent Application Publication
(10) Pub. No.: US 2016/0372627 A1
(43) Pub. Date: Dec. 22, 2016

(54) SEMICONDUCTOR LIGHT EMITTING DEVICE

(71) Applicant: KABUSHIKI KAISHA TOSHIBA, Tokyo (JP)

(72) Inventors: Masakazu SAWANO, Nonoichi Ishikawa (JP); Hiroshi KATSUNO, Komatsu Ishikawa (JP); Kazuyuki MIYABE, Kanazawa Ishikawa (JP)

(21) Appl. No.: 15/051,433

(22) Filed: Feb. 23, 2016

(30) Foreign Application Priority Data
Jun. 18, 2015 (JP) 2015-122754

(51) Int. Cl. H01L 33/00; H01L 33/58; H01L 33/10; H01L 33/06; H01L 33/32

(52) U.S. Cl. CPC H01L 33/0025; H01L 33/06; H01L 33/325; H01L 33/10; H01L 33/58

(57) ABSTRACT

A semiconductor light emitting device includes a light emitting body that includes a light emitting layer between first and second semiconductor layers, a substrate on the second semiconductor layer side of the light emitting body layer, a first metal layer electrically connected to one of the first and second semiconductor layers, and extending therefrom between the substrate and the light emitting body to a location outside of the perimeter light emitting body, a conductive layer overlying the portion of the first metal layer which extends outside the perimeter of the light emitting body, and a second metal layer disposed on a portion of the conductive layer overlying the portion of the first metal layer. The second metal layer is located in part within opening extending inwardly of a side surface of the light emitting body. A sidewall of the opening connects to the side surface along a curved surface.

### CROSS-REFERENCE TO RELATED APPLICATION

This application is based upon and claims the benefit of priority from Japanese Patent Application No. 2015-122754, filed Jun. 18, 2015, the entire contents of which are incorporated herein by reference.

### FIELD

Exemplary embodiments described herein relate to a semiconductor light emitting device.

### BACKGROUND

Semiconductor light emitting devices are provided with, for example, a light emitting body in which a p-type semiconductor layer, a light emitting layer, and an n-type semiconductor layer are stacked one over the other, and an electrode which connects the light emitting body to an external circuit. In addition, in the manufacturing process of the semiconductor light emitting device, a method for properly protecting electrodes with respect to the etching of the p-type semiconductor layer, the n-type semiconductor layer, and the light emitting layer, and improving reliability of the semiconductor light emitting device is required.

### DESCRIPTION OF THE DRAWINGS

FIG. 1A is a plan view schematically illustrating a semiconductor light emitting device according to a first embodiment, and FIG. 1B is a sectional view of the semiconductor light emitting device of FIG. 1A taken at line IB-IB, schematically illustrating the semiconductor light emitting device according to the first embodiment.

FIG. 2A is another plan view schematically illustrating the semiconductor light emitting device according to the first embodiment, and FIG. 2B is a sectional view of the semiconductor light emitting device of FIG. 2A schematically illustrating a main portion of the semiconductor light emitting device.

FIGS. 3A to 3C are sectional views schematically illustrating steps of the manufacturing process of the semiconductor light emitting device according to the first embodiment.

FIGS. 4A to 4C are sectional views schematically illustrating steps of the manufacturing process following the step illustrated in FIG. 3C.

FIGS. 5A and 5B are sectional views schematically illustrating steps of the manufacturing process following the step illustrated in FIG. 4C.

FIGS. 6A and 6B are sectional views schematically illustrating steps of the manufacturing process following the step illustrated in FIG. 5B.

FIGS. 7A and 7B are sectional views schematically illustrating steps of the manufacturing process following the step illustrated in FIG. 6B.

FIG. 8A is a sectional view schematically illustrating a feature of the semiconductor light emitting device according to the first embodiment, and FIG. 8B is a sectional view schematically illustrating a main portion of the semiconductor light emitting device according to a comparative example.

FIGS. 9A and 9B are plan views schematically illustrating a main portion of the semiconductor light emitting device according to the first embodiment.

FIG. 10A is a plan view schematically illustrating a semiconductor light emitting device according to a second embodiment, and FIGS. 10B and 10C are sectional views schematically illustrating the semiconductor light emitting device of FIG. 10A according to the second embodiment.

### DETAILED DESCRIPTION

Embodiments provide a semiconductor light emitting device having improved reliability.

In general, according to one embodiment, there is provided a semiconductor light emitting device including a light emitting body comprising a first semiconductor layer of a first conductivity type, a second semiconductor layer of a second conductivity type, and a light emitting layer provided between the first semiconductor layer and the second semiconductor layer, a substrate located on the second semiconductor layer side of the light emitting body layer, a first metal layer electrically connected to one of the first semiconductor layer and the second semiconductor layer at a location between the substrate and the light emitting body, including an extending portion extending over the substrate from a location between the substrate and the light emitting body to a location outside the perimeter of the light emitting body, a conductive layer overlying the extending portion of the first metal layer extending to the location outside the perimeter of the light emitting body, and extending to a location between the light emitting body and the first metal layer, and a second metal layer located adjacent to, and spaced from, the light emitting body on the substrate, and on a portion of the conductive layer overlying the extending portion. The light emitting body has a first surface comprising a surface of the first semiconductor layer, a second surface comprising a surface of the second semiconductor layer, and a side surface including an outer edge of the first semiconductor layer. The light emitting body includes an opening extending inwardly from the side surface. The second metal layer is located at least partially within the opening extending inwardly from the side surface. A sidewall of the opening extending inwardly of the side surface connects to the side surface along a curved surface.

Hereinafter, the embodiment will be described with reference to the drawings. The same components in the drawings are given the same reference numerals, and the description will focus on the different components and the specific description of the same reference numerals may be omitted when appropriate. In addition, the drawings are schematic or conceptual, and thus the relationship between the thickness and the width of each portion, and the size ratio between portions are not necessarily the same as reality. Moreover, even when representing the same components, dimensions and ratios are expressed differently depending on the drawings in some cases.

Note that, a semiconductor light emitting device which will be described below is merely an example; therefore, the embodiment is not limited thereto. Technical features of the semiconductor light emitting device are commonly applied to the respective embodiments as long as the technical features are technically applicable.

### First Embodiment

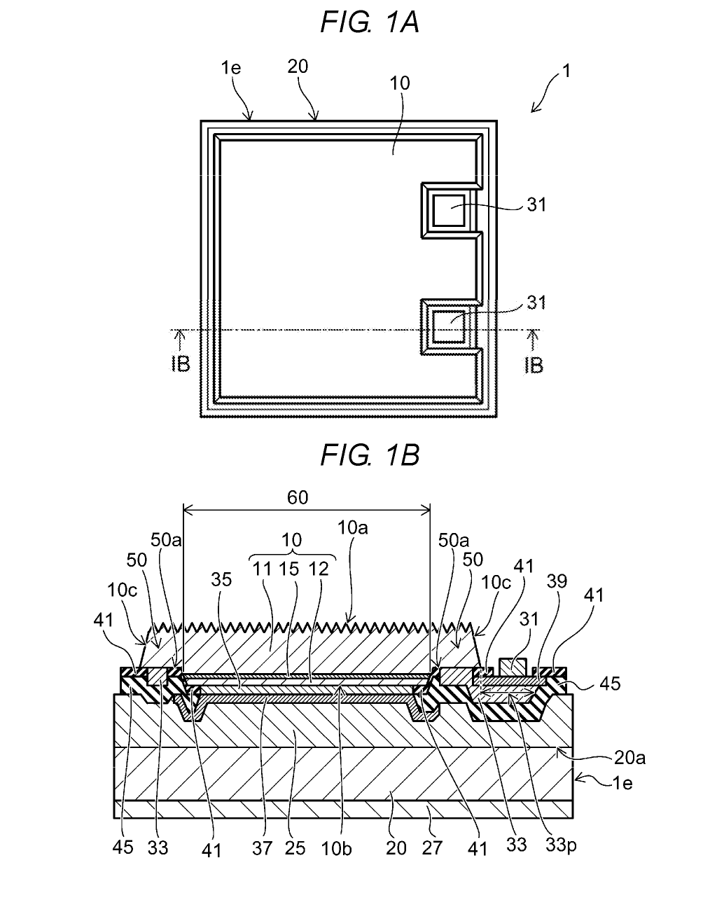

FIG. 1A is a top view schematically illustrating a semiconductor light emitting device 1 according to the first embodiment, and FIG. 1B is a sectional view schematically illustrating the semiconductor light emitting device 1 in section along line IB-IB of FIG. 1A. The semiconductor light emitting device 1 is a chip-like light source and is, for example, mounted on a mount substrate.

As illustrated in FIG. 1A, the semiconductor light emitting device 1 is provided with a light emitting body 10 and a substrate 20. The light emitting body 10 is provided on the substrate 20. The semiconductor light emitting device 1 includes the light emitting body 10 and bonding pads 31, which are disposed side by side adjacent to a side surface of the substrate 20 with a portion of the light emitting body extending therebetween.

As illustrated in FIG. 1B, the light emitting body 10 is bonded to the substrate 20 by a bonding layer 25. The light emitting body 10 includes a first semiconductor layer of a first conductivity type (hereinafter, an n-type semiconductor layer 11), a second semiconductor layer of a second conductivity type (hereinafter, a p-type semiconductor layer 12), and a light emitting layer 15. The light emitting body 10 has a structure in which the n-type semiconductor layer 11, the light emitting layer 15, and the p-type semiconductor layer 12 are sequentially stacked one over the other. Hereinafter, the first conductivity type will be referred to as an n type, and the second conductivity type will be referred to as a p type; however, the embodiment is not limited thereto. The embodiment also includes a case where the first conductivity type is referred to as p type and the second conductivity type is referred to as an n type.

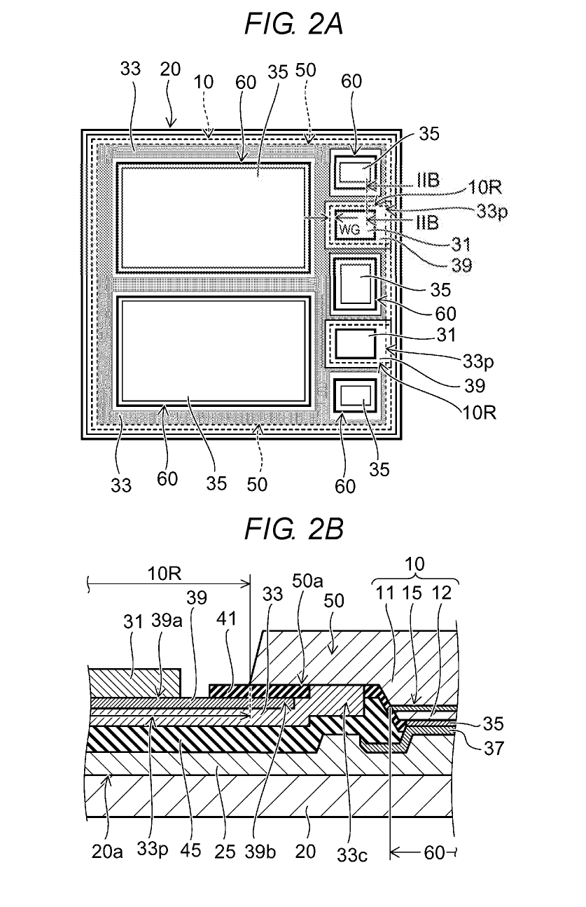

The light emitting body 10 includes a first surface 10a including a surface of the n-type semiconductor layer 11 facing away from the light emitting layer 15, a second surface 10b including a surface of the p-type semiconductor layer 12 facing away from the light emitting layer 15 and the first surface 10a, and a side surface 10c including an outer edge of the n-type semiconductor layer 11. In addition, the light emitting body 10 includes a non-light emitting portion 50 and a light emitting portion 60. A step is provided between the non-light emitting portion 50 and the light emitting portion 60, and the non-light emitting portion 50 includes a surface 50a which has a depth from the second surface 10b extending inwardly thereof to a location in the n-type semiconductor layer 11. The light emitting portion 60 includes the n-type semiconductor layer 11, the light emitting layer 15, and the p-type semiconductor layer 12, and the non-light emitting portion 50 surrounds the light emitting area 60 in the plane parallel with the second surface 10b (refer to FIG. 2A).

Light emitted from the light emitting layer 15 is emitted to the outside of the light emitting body 10 mainly from the first surface 10a. The first surface 10a has a light extraction structure. The light extraction structure suppresses total reflection of the emitted light and improves the efficiency of light extraction therefrom. For example, the first surface 10a is provided with fine projections and is roughened.

The semiconductor light emitting device 1 includes on the second surface 10b side of the light emitting body 10, an n-type electrode 33 (a first metal layer), a p-type electrode 35, and a metal layer 37. The n-type electrode 33 is electrically connected to the n-type semiconductor layer 11 at the surface 50a of the non-light emitting portion 50. The p-type electrode 35 is electrically connected to the p-type semiconductor layer 12 on the second surface 10b. The metal layer 37 is provided on the p-type electrode 35 on the side thereof opposite to the p-type semiconductor layer 12. The n-type electrode 33, the p-type electrode 35, and the metal layer 37 preferably include a material having high reflectance with respect to the light emitted from the light emitting layer 15. The n-type electrode 33 contains, for example, aluminum (Al). The p-type electrode 35 and the metal layer 37 may contain, for example, silver (Ag). Meanwhile, a structure in which the metal layer 37 is not provided may be employed.

The semiconductor light emitting device 1 includes a dielectric film 41 and a dielectric film 45. The dielectric film 41 covers the step between the non-light emitting portion 50 and the light emitting portion 60 and the portion on the surface 50a of the non-light emitting portion 50 which is not in contact with the n-type electrode 33 at the surface 50a of the non-light emitting portion 50. The dielectric film 41 covers and protects the outer edge of the light emitting layer 15 from adjacent ambient conditions, such as humidity and moisture. The dielectric film 45 covers the entire non-light emitting portion 50. The dielectric film 45 covers the portion of the n-type electrode 33 extending through the dielectric film 41 in a direction away from surface 50a of the non-light emitting portion 50, and thus electrically insulates the n-type electrode 33 from the substrate 20 and the bonding layer 25. The dielectric film 45 may be the same material as the dielectric film 41.

The metal layer 37 extends on the dielectric film 45, and extends over the portions of the dielectric films 41 and 45 located between the n-type electrode 33 and the p-type electrode 35. The metal layer 37 extends between the dielectric films 41 and 45 and reflects light emitted from the light emitting layer 15 propagating in the direction of the substrate 20, such that the light returns to the direction of the first surface 10a in the area between the n-type electrode 33 and the p-type electrode 35.

The bonding layer 25 is provided so as to cover the metal layer 37 and the dielectric film 45. The bonding layer 25 is a conductive layer containing bonding metal which is formed of a solder such as gold-tin (AuSn) and nickel-tin (NiSn). The p-type electrode 35 is electrically connected to the bonding layer 25 by the metal layer 37. In addition, the bonding layer 25 is electrically connected to the conductive substrate 20. The bonding layer 25 comprises, for example, a high-melting point metal film such as titanium (Ti) and titanium-tungsten (TiW). The high-melting point metal film serves as a barrier film which prevents the solder such as gold-tin (AuSn) and nickel-tin (NiSn) of the bonding metal contained by the bonding layer 25 from spreading to the p-type electrode 35 and the metal layer 37. An electrode 27 is provided on the rear surface side of the substrate 20. The electrode 27 is, for example, a stacked film of Ti/Pt/Au, and has a total film thickness of 800 nm, for example. The electrode 27 is connected to an external circuit via, for example, the mounting substrate (not shown).

In contrast, the n-type electrode 33 is connected to, for example, an external circuit via a metallic wire such as gold or aluminum which is connected to a bonding pad 31 (a second metal layer). The n-type electrode 33 includes an extending portion 33p which extends from a location adjacent to a side of the light emitting body 10 and below the bonding pad 31. The bonding pad 31 is located on the extending portion 33p with a conductive layer 39 disposed therebetween. The conductive layer 39 covers the extending portion 33p and extends to a location below and spaced from the light emitting body 10 by a portion of the dielectric film 41. In addition, the conductive layer 39 extends in the direction of a chip side 1e from the bonding pad 31, and for example, extends further toward the chip side 1e than does the extending portion 33p.

The extending portion 33p extends over the top surface 20a of the substrate 20. Portions of the dielectric film 45 and the bonding layer 25 are interposed between the extending portion 33p and the substrate 20. The extending portion 33p is electrically insulated from the substrate 20 and the bonding layer 25 by the dielectric film 45.

FIG. 2A is another top view schematically illustrating the semiconductor light emitting device 1. FIG. 2B is a schematic view illustrating a cross section of the light emitting device 1 along line IIB-IIB in FIG. 2A.

FIG. 2A is a schematic view illustrating the surface of the electrode under the light emitting body 10. A dashed line (at end of dashed arrow with reference numeral 10) which is shown in FIG. 2A represents an outer edge of the light emitting body 10. The light emitting body 10 also includes open regions 10R in which the side surface 10c is retracted inwardly of the side of the light emitting device along the direction parallel with the second surface 10b. The n-type electrode 33 extends from the surface 50a of the non-light emitting portion 50. The n-type electrode 33 is provided immediately below the light emitting body 10 and surrounds the light emitting area 60.

The semiconductor light emitting device 1 includes, for example, five light emitting areas 60. The p-type electrode 35 is provided in each of the light emitting areas 60. Each of the light emitting area 60 includes the light emitting layer 15. For example, a driving current of the semiconductor light emitting device 1 is supplied from the electrode 27 on the rear surface side of the substrate 20. The driving current flows through the substrate 20 and bonding layer 25 and thence into the p-type electrode 35. The current then flows to the n-type electrode 33 via the light emitting layer 15 and n-type semiconductor layer. Owing to this configuration, the semiconductor light emitting device 1 causes the five light emitting areas 60 to emit light.

The n-type electrode 33 includes the extending portions 33p which extend to a location outward of the side or edge of the light emitting body 10. The extending portions 33p are positioned in the open regions 10R. The conductive layer 39 covers the entire extending portion 33p. In addition, the conductive layer 39 extends between a portion of the light emitting body 10 and the substrate 20. The bonding pad 31 is provided on the conductive layer 39. A gap W_{G} between a side of the bonding pad 31 and an adjacent side of the light emitting body 10 is preferably equal to or less than 50 μm.

As illustrated in FIG. 2B, the n-type electrode 33 is configured to contact the n-type semiconductor layer 11 on the surface 50a of the non-light emitting portion 50 of the semiconductor layer 11 of the light emitting body 10. The n-type electrode 33 includes a portion (the extending portion 33p) which extends outwardly of a side or edge of the light emitting body 10. The extending portion 33p extends over the top surface 20a of the substrate 20. The conductive layer 39 includes a first portion 39a which covers the extending portion 33p, and a second portion 39b which extends between the light emitting body 10 and the n-type electrode 33. That is, when the chip surface is viewed from above, the conductive layer 39 includes a portion underlying a portion of the light emitting body 10. In addition, when the chip surface is viewed from above, the outer edge of the conductive layer 39 is positioned between a portion (a contact portion 33c) in which the n-type electrode 33 comes into contact with the n-type semiconductor layer 11, and the outer edge of the light emitting body 10. The dielectric film 41 is positioned between the light emitting body 10 and the conductive layer 39, and extends outwardly of the edge or side of the light emitting body 10 along the conductive layer 39.

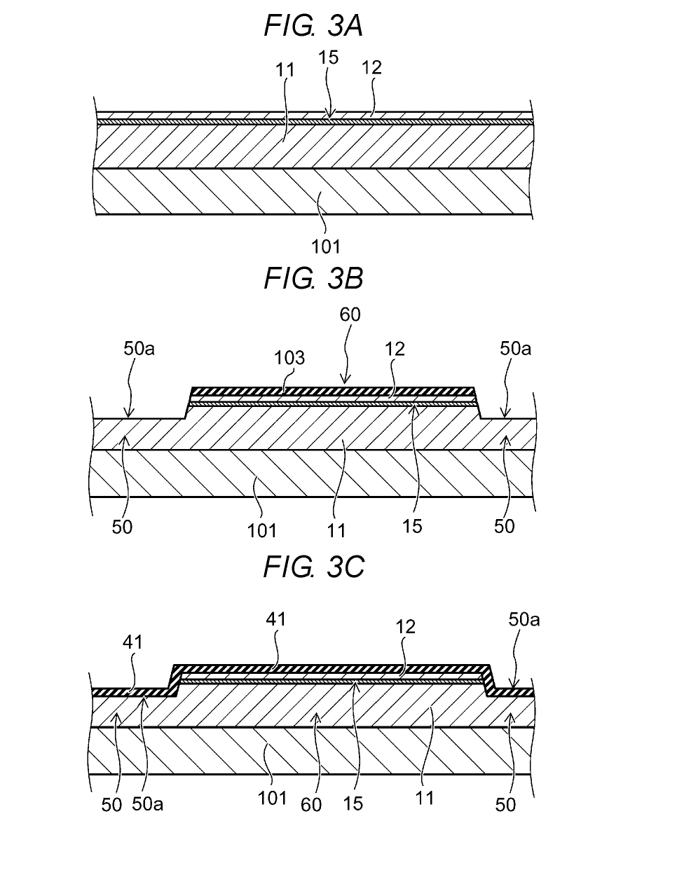

Next, a manufacturing method of the semiconductor light emitting device 1 will be described with reference to FIG. 3A to FIG. 7B. FIG. 3A to FIG. 7B are schematic sectional views sequentially illustrating the result of steps in the manufacturing process of the semiconductor light emitting device 1.

As illustrated in FIG. 3A, the n-type semiconductor layer 11, the light emitting layer 15, and the p-type semiconductor layer 12 are sequentially stacked on a substrate 101. In the specification, the stacked state includes not only a state in which the layers directly come into contact with each other, but also a state in which the layers interpose other elements therebetween.

The substrate 101 is, for example, a silicon substrate or a sapphire substrate. The n-type semiconductor layer 11, the p-type semiconductor layer 12, and the light emitting layer 15 respectively include a nitride semiconductor. The n-type semiconductor layer 11, the p-type semiconductor layer 12, and the light emitting layer 15 respectively include, for example, AlₓGa_{1-x-y}In_{y}N (x≧0, y≧0, x+y≦1).

The n-type semiconductor layer 11 includes, for example, a Si-doped n-type GaN contact layer and a Si-doped n-type AlGaN clad layer. The Si-doped n-type AlGaN clad layer is arranged between the Si-doped n-type GaN contact layer and the light emitting layer 15. The n-type semiconductor layer 11 may further include a buffer layer, or the Si-doped n-type GaN contact layer may be arranged between a GaN buffer layer and the Si-doped n-type AlGaN clad layer. For example, any one of AlN, AlGaN, and GaN or a combination thereof can be used as the buffer layer.

The light emitting layer 15 has, for example, a multiple quantum well (MQW) structure. In the MQW structure, for example, a plurality of barrier layers and a plurality of well layers are stacked in an alternating manner. For example, AlGaInN can be used as the well layer. For example, GaInN can be also used as the well layer.

Si-doped n-type AlGaN can be used as the barrier layer, for example. Si-doped n-type Al_{0.1}Ga_{0.9}N can be used as the barrier layer for example. The thickness of the barrier layer is, for example, in a range of from 2 nm to 30 nm. Among the plurality of barrier layers, the barrier layer (a p-side barrier layer) which is the closest to the p-type semiconductor layer 12 may be different from other barrier layers, and may be thicker or thinner than other barrier layers.

A wavelength (a peak wavelength) of the light (emitted light) which is emitted from the light emitting layer 15 is, for example, in a range of from 210 nm to 700 nm. The peak wavelength of the emitted light may be, for example, in a range of from 370 nm to 480 nm.

The p-type semiconductor layer 12 includes, for example, a non-doped AlGaN spacer layer, an Mg-doped p-type AlGaN clad layer, an Mg-doped p-type GaN contact layer, and a highly concentrated Mg-doped p-type GaN contact layer. The Mg-doped p-type GaN contact layer is arranged between the highly concentrated Mg-doped p-type GaN contact layer and the light emitting layer 15. The Mg-doped p-type AlGaN contact layer is arranged between the Mg-doped p-type GaN clad layer and the light emitting layer 15. The non-doped AlGaN spacer layer is arranged between the Mg-doped p-type AlGaN clad layer and the light emitting layer 15. For example, the p-type semiconductor layer 12 includes a non-doped Al_{0.11}Ga_{0.89}N spacer layer, an Mg-doped p-type Al_{0.28}Ga_{0.72}N clad layer, the Mg-doped p-type GaN contact layer, and a highly concentrated Mg-doped p-type GaN contact layer.

Meanwhile, in the above-described semiconductor layer, a composition, a compositional ratio, types of impurities, impurity concentration, and the thickness are illustrative, and various modifications are possible.

The non-light emitting portion 50 and a light emitting portion 60 are formed as illustrated in FIG. 3B. For example, a portion of the p-type semiconductor layer 12 or a portion of the light emitting layer 15 is selectively removed by selective etching using a hard mask 103. The hard mask 103 is, for example, a silicon oxide film. The etching-depth is, for example, in a range of from 0.1 μm to 100 μm. Preferably, the etching-depth is in a range of from 0.4 μm to 2 μm. The non-light emitting portion 50 is formed such that the n-type semiconductor layer 11 is exposed at the surface 50a the non-light emitting portion 50.

As illustrated in FIG. 3C, the dielectric film 41 is formed so as to cover a top surface of the p-type semiconductor layer 12, a step area between the surface of the non-light emitting portion 50 and the light emitting portion 60, and the surface 50a of the non-light emitting portion 50. The dielectric film 41 is, for example, a silicon oxide film or a silicon nitride film. In addition, the dielectric film 41 has, for example, a stacked structure, and may have a structure in which the silicon oxide film and the silicon nitride film are stacked. The hard mask 103 is removed by etching before the dielectric film 41 is formed.

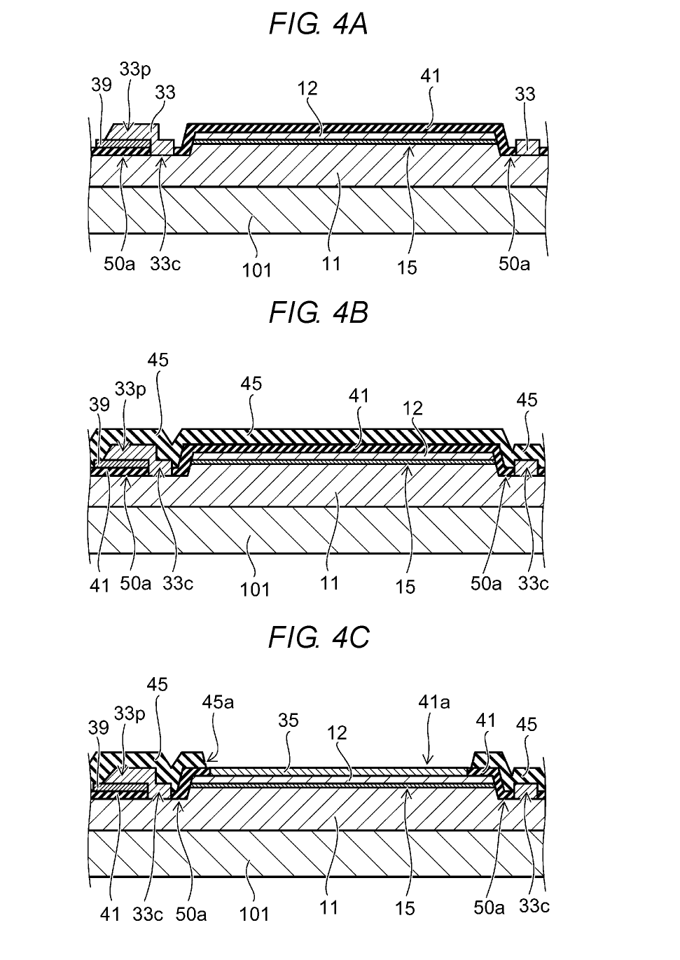

As illustrated in FIG. 4A, portions of the dielectric film 41 provided on the surface 50a of the non-light emitting portion 50 are selectively removed so as to expose the n-type semiconductor in the non-light emitting portion 50 of the layer 11. Subsequently, the n-type electrode 33, which is electrically connected to the n-type semiconductor layer 11, is formed. A material of the n-type electrode 33 has, for example, ohmic contact properties and high light reflectance with respect to the n-type semiconductor layer 11, and includes at least one of aluminum (Al) and silver (Ag).

In addition, the conductive layer 39 is selectively formed on the dielectric film 41 in the non-light emitting portion 50 before the n-type electrode 33 is formed. The conductive layer 39 is provided in the vicinity of a portion (the contact portion 33c) in which the n-type electrode 33 comes into contact with the n-type semiconductor layer 11, and also covers the portion in which the bonding pad 31 is to be formed. The n-type electrode 33 includes the extending portion 33p extending over a portion of the conductive layer 39. The conductive layer 39 is, for example, titanium nitride (TiN). In addition, the conductive layer 39 may be a composite layer including at least one of a metal layer, a conductive metal nitride layer, and a conductive metal oxide layer.

As illustrated in FIG. 4B, the dielectric film 45 is formed so as to cover the n-type electrode 33, the conductive layer 39, and the dielectric film 41. The dielectric film 45 is, for example, a silicon oxide film.

As illustrated in FIG. 4C, the dielectric film 41 and the dielectric film 45 are selectively etched so as to form opening portions 45a and 41a. Owing to this configuration, the p-type semiconductor layer 12 is exposed in the opening portions 45a, 41a. In this stage, in the non-light emitting portion 50, the dielectric film 41 which covers the surface 50a, and the dielectric film 45 which covers the n-type electrode 33, the conductive layer 39, and the dielectric film 41 remain except for a portion which comes into contact with the contact portion 33c of the n-type electrode 33. Then, the p-type electrode 35 which is electrically connected to the p-type semiconductor layer 12 is formed. The p-type electrode 35 includes, for example, Ag.

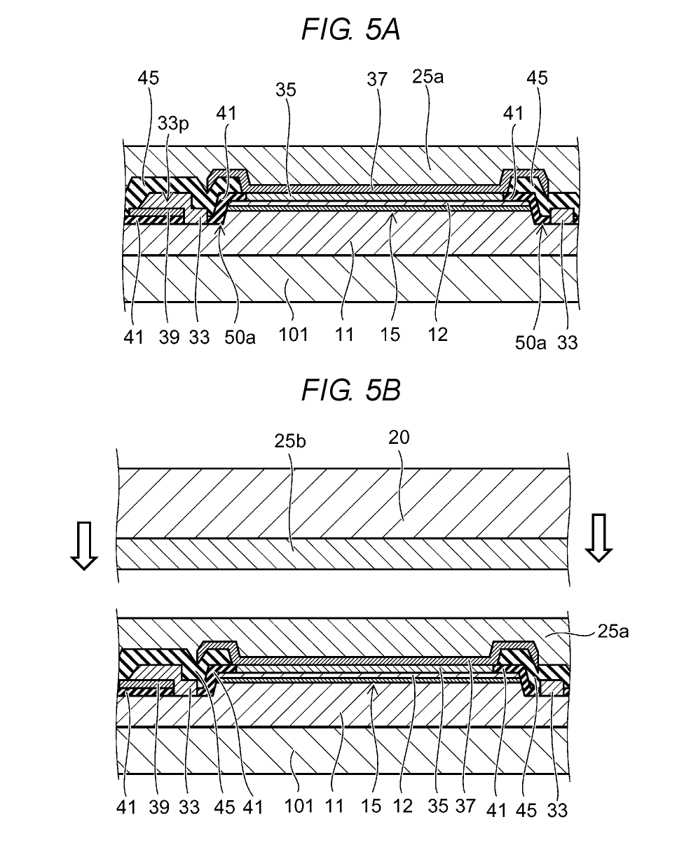

As illustrated in FIG. 5A, the metal layer 37 is formed on the p-type electrode 35. The metal layer 37 extends from the ends of the p-type electrode 35 on a portion of the dielectric film 45, and overlies the step between the non-light emitting portion 50 and the light emitting portion 60 and a portion of the surface 50a of the non-light emitting portion 50 via the dielectric films 41 and 45. The metal layer 37 covers the portions of the dielectric films 41 and 45 which are arranged between the n-type electrode 33 and the p-type electrode 35. The metal layer 37 includes, for example, Ag.

Further, a bonding layer 25a which covers the metal layer 37 and the exposed portion of the dielectric film 45 is formed. The bonding layer 25a includes, for example, a high-melting point metal film including at least one of Ti, Pt, and Ni, and bonding metal. The bonding metal includes, for example, at least one of Ni—Sn-based bonding metal, Au—Sn-based bonding metal, Bi—Sn-based bonding metal, Sn—Cu-based bonding metal, Sn—In-based bonding metal, Sn—Ag-based bonding metal, Sn—Pb-based bonding metal, Pb—Sn—Sb-based bonding metal, Sn—Sb-based bonding metal, Sn—Pb—Bi-based bonding metal, Sn—Pb—Cu-based bonding metal, Sn—Pb—Ag-based bonding metal, and Pb—Ag-based bonding metal. The high-melting point metal film including at least one of Ti, Pt, and Ni is provided between the bonding metal and the metal layer 37, and is provided between the bonding metal and the dielectric film 45.

As illustrated in FIG. 5B, the substrate 101 on which the bonding layer 25a is formed and the substrate 20 face each other. The substrate 20 includes a bonding layer 25b formed thereon. Then, the bonding layer 25b of the substrate 20 is arranged so as to face the bonding layer 25a of the substrate 101.

The bonding layer 25b includes, for example, a high-melting point metal film including at least one of Ti, Pt, and Ni, and bonding metal. The bonding metal includes, for example, at least one of Ni—Sn-based bonding metal, Au—Sn-based bonding metal, Bi—Sn-based bonding metal, Sn—Cu-based bonding metal, Sn—In-based bonding metal, Sn—Ag-based bonding metal, Sn—Pb-based bonding metal, Pb—Sn—Sb-based bonding metal, Sn—Sb-based bonding metal, Sn—Pb—Bi-based bonding metal, Sn—Pb—Cu-based bonding metal, Sn—Pb—Ag-based bonding metal, and Pb—Ag-based bonding metal. The high-melting point metal film including at least one of Ti, Pt, and Ni is provided between the bonding metal and the substrate 20.

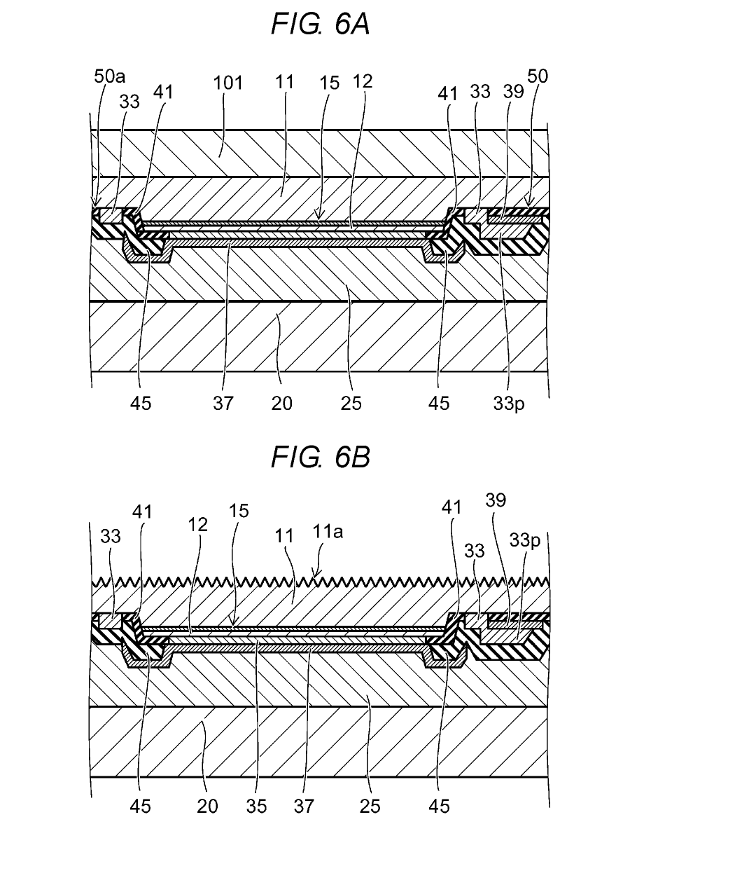

As illustrated in FIG. 6A, the bonding layers 25a and 25b come into contact with each other and the substrate 101 and the substrate 20 are thermally compressed to each other under the application of heat energy. Owing to this configuration, the bonding layers 25a and 25b are integrally formed so as to form the bonding layer 25. In addition, FIG. 6A is a sectional view, which is the sectional view flipped from that of FIG. 5B, illustrating a state in which the respective semiconductor layers and the substrate 101 are arranged on the substrate 20 with the bonding layer 25 therebetween.

As illustrated in FIG. 6B, the substrate 101 has been removed. For example, when the substrate 101 is a silicon substrate, the substrate 101 is removed by using a method such as grinding and dry etching (for example, reactive ion etching (RIE)). For example, when the substrate 101 is the sapphire substrate, the substrate 101 is removed by using a laser lift off (LLO) method. Further, a surface 11a of the n-type semiconductor layer 11 has fine projections formed thereon and is roughened. For example, the surface 11a of the n-type semiconductor layer 11 is roughened through a wet etching process using an alkali, or by RIE, to form the fine protrusions.

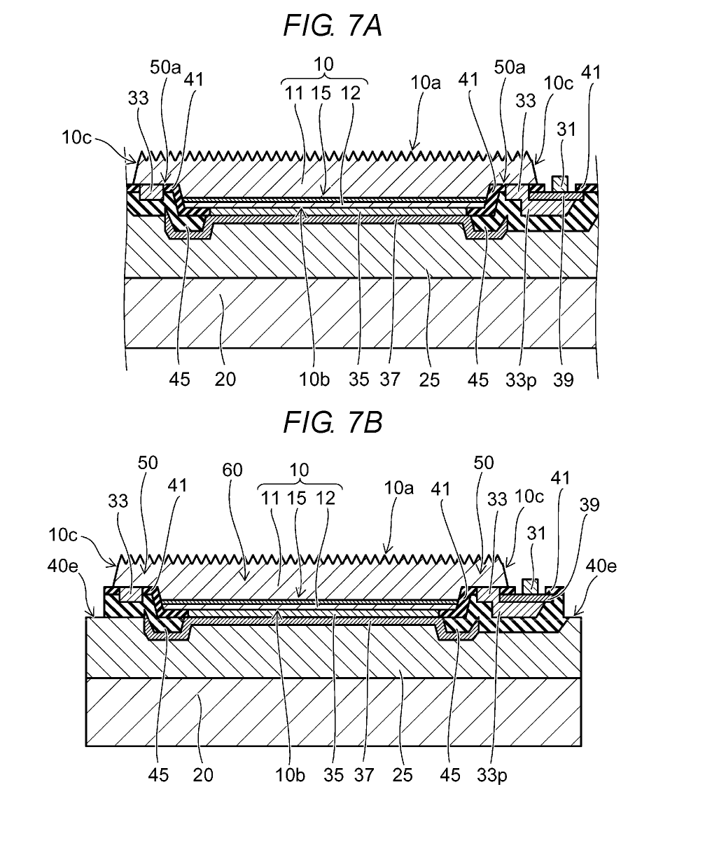

As illustrated in FIG. 7A, the n-type semiconductor layer 11 in the non-light emitting portion 50 is selectively removed so as to form the light emitting body 10. For example, the n-type semiconductor layer 11, the light emitting layer 15, and the p-type semiconductor layer 12 are sequentially etched in the non-light emitting portion 50 by using a method such as RIE or wet etching. At this time, a portion of the dielectric film 41 is exposed in the vicinity of the side or edge of the light emitting body 10. The n-type semiconductor layer 11 is removed using, for example, a hot phosphoric acid for etching thereof and of the light emitting layer 15 and the p-type semiconductor layer 12 in the non-light emitting portion 50.

The dielectric film 41 has, for example, an etching resistance with respect to the etchant such that the n-type semiconductor layer 11 can be removed and the structure immediately below the n-type semiconductor layer 11 is protected by the dielectric film 41. Further, the portion of the dielectric film 41 in which the bonding pad 31 is formed is selectively removed, thereby exposing the conductive layer 39. Subsequently, the bonding pad 31 is formed on the exposed portion of the conductive layer 39.

As illustrated in FIG. 7B, the dielectric film 41 or the dielectric film 45 which is in the vicinity of the sides or edge of the light emitting body 10 is selectively removed so as to form a dicing area 40e between adjacent devices commonly formed on a single substrate 20. Subsequently, for example, the bonding layer 25 and the substrate 20 are cut by using a dicer or a scriber so as to make the semiconductor light emitting device 1 into a singulated chip.

In the above-described example, in addition to the silicon oxide film, a silicon nitride or a silicon oxynitride can be used for the dielectric films 41 and 45. In addition, a metallic oxide which is formed of at least one of Al, Zr, Ti, Nb, Hf, and the like, or a metallic nitride which is formed of at least one of the aforementioned materials.

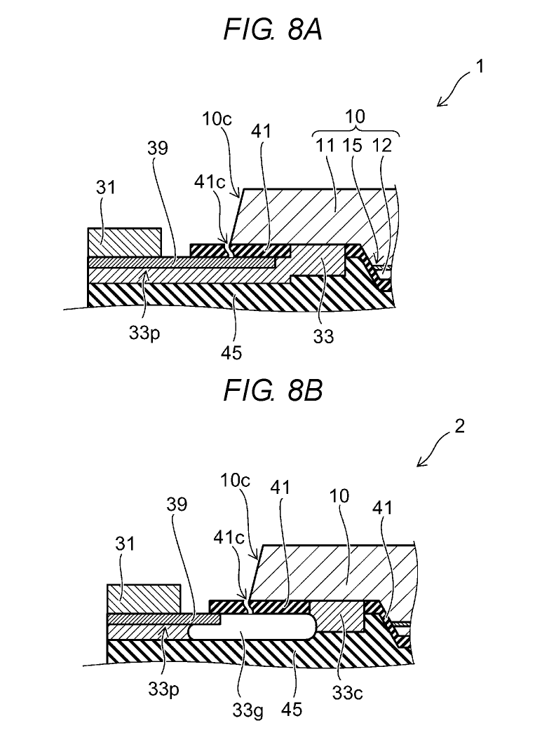

Next, a function of the conductive layer 39 will be described with reference to FIGS. 8A and 8B. FIG. 8A is a sectional view schematically illustrating a feature of the semiconductor light emitting device 1. FIG. 8B is a sectional view schematically illustrating a main portion of a semiconductor light emitting device 2 according to the Comparative example.

The n-type semiconductor layer 11, the light emitting layer 15, and the p-type semiconductor layer 12 include, for example, internal stress caused by a difference of the coefficient of thermal expansion between the n-type semiconductor layer 11, the light emitting layer 15, and the p-type semiconductor layer 12, with the substrate 101, when grown epitaxially. A portion of the internal stress is maintained in the substrate 20 even in as state where the substrate 101 is removed. In addition, when portions of the n-type semiconductor layer 11 are selectively removed in order to form the light emitting body 10, a stress difference between a portion immediately below the light emitting body 10, and a portion in which the n-type semiconductor layer 11 is removed can generate a crack 41c in the dielectric film 41.

As illustrated in FIG. 8A, the conductive layer 39 extends between the light emitting body 10 and the extending portion 33p of the n-type electrode 33 while being positioned immediately below the dielectric film 41. For example, a material having a resistance with respect to the etchant used to remove the n-type semiconductor layer 11 is used for the conductive layer 39. Owing to this configuration, the conductive layer 39 functions in part to prevent infiltration of the etchant for the n-type semiconductor layer 11, such as a hot phosphoric acid, through the crack 41c and into contact with the n-type electrode 33, including portions of the contact portion 33c and extending portion 33p thereof.

On the other hand, in the semiconductor light emitting device 2 as illustrated in FIG. 8B, the conductive layer 39 is provided on the extending portion 33p which forms the bonding pad 31, but does not extend below the light emitting body 10. In addition, in the outer edge of the light emitting body 10, the n-type electrode 33 is positioned immediately below the dielectric film 41. Because it is not easy to select a material which forms ohmic contact with the n-type semiconductor layer 11, has high reflectance with respect to the light emitted from the light emitting layer 15, and has a resistance with respect to etchant on the n-type semiconductor layer 11, a material having a low etching resistance to the material used to etch the n-type semiconductor layer 11 is used for the n-type electrode 33. For this reason, etchant which infiltrates through the crack 41c etches the portion of the n-type electrode 33 contact portion 33c and extending portion adjacent to the opening of the crack through the dielectric film 41 as well. As a result, one or more cavities 33g are generated between the contact portion 33c and the extending portion 33p of the n-type electrode 33 where crack 41c is present, thereby reducing the electrical flow path area of the n-type electrode 33 and increasing the electrical resistance between the bonding pad 31 and the n-type semiconductor layer 11, thereby increasing the operating voltage of the semiconductor light emitting device 2. In addition, it is likely that ion migration is generated in a metal including Al which is exposed to the inside of the cavity 33g, for example, by being exposed to the outside air.

The conductive layer 39 in the embodiment protects the n-type electrode 33 in the etching step of the n-type semiconductor layer 11, and thus prevents the electrical resistance between the bonding pad 31 and the n-type semiconductor layer 11 from being increased so as to suppress the ion migration (electrochemical migration of, for example, metal atoms). From this result, the manufacturing yield of the semiconductor light emitting device 1 is increased and the reliability thereof is improved.

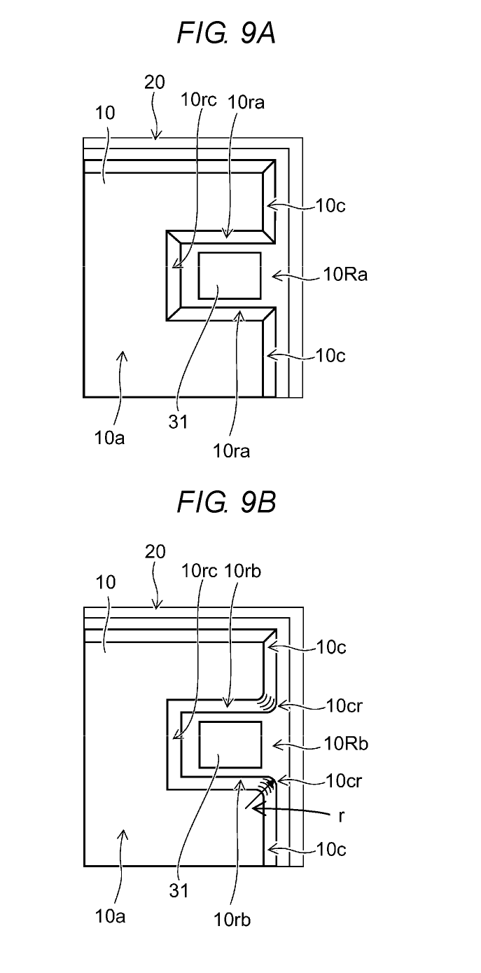

FIGS. 9A and 9B are top views schematically illustrating a portion of the semiconductor light emitting device 1. FIGS. 9A and 9B illustrate open regions 10Ra and 10Rb each of which is provided with the bonding pad 31.

As illustrated in FIG. 9A, the open region 10Ra is provided in the light emitting body 10. The open region 10Ra extends from the side of the light emitting region 10 in the direction of the interior of the light emitting body 10, on the first surface 10a. The open region 10Ra is bounded on three sides by a wall surface 10rc which is positioned inwardly of the side surface 10c, and wall surfaces 10ra which extend between the side surface 10c and the wall surface 10rc on opposite sides of the open region 10 Ra. The bonding pad 31 is positioned between the two wall surfaces 10ra which face each other, and the wall surface 10rc and the edge of the chip

On the other hand, in the example illustrated in FIG. 9B, an open region 10Rb is provided in the light emitting body 10. The open region 10Rb extends inwardly of the light emitting body 10 from side surface 10c, on the first surface 10a. The open region 10Rb is bounded, inwardly of the light emitting body 10, by the wall surface 10rc, and opposed wall surfaces 10rb extend therefrom to the side surface 10c. The bonding pad 31 is positioned between the two wall surfaces 10rb which face each other and the wall surface 10rc and the side or edge of the chip. The wall surface 10rb is connected to the side surface 10c via a radiused or curved surface 10cr.

In the example in FIG. 9B, for example, when a radius of curvature r of the curved surface 10cr is set as 30 nm, the crack 41c will in the dielectric film 41 immediately below the bent surface 10cr (refer to FIG. 8A). In contrast, in the example illustrated in FIG. 9A, the crack does not occur in the dielectric film 41. The example illustrated in FIG. 9A corresponds to a case where the radius of curvature of the curved surface 10cr is set as 0 (zero). That is, when the radius of curvature of the curved surface 10cr is 0 μm or greater and less than 30 μm, it is possible to prevent the crack 41c from occurring in the dielectric film 41. Owing to this configuration, it is possible to further improve reliability of the semiconductor light emitting device 1.

### Second Embodiment

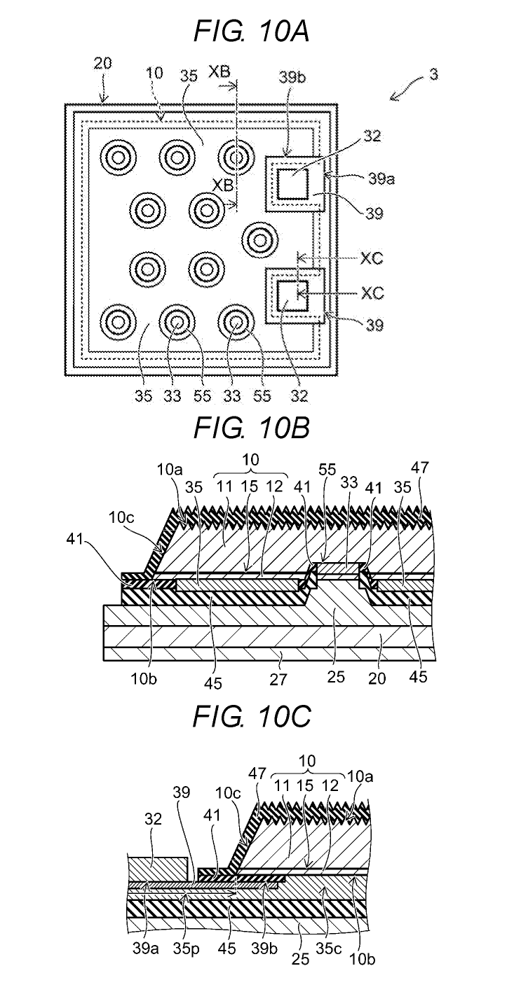

FIG. 10A is a top view schematically illustrating a semiconductor light emitting device 3 according to the second embodiment. FIGS. 10B and 10C are sectional views schematically illustrating a main portion of the semiconductor light emitting device 3. FIG. 10B illustrates a cross section taken along line XB-XB in FIG. 10A, and FIG. 10C illustrates a cross section taken along line XC-XC in FIG. 10A.

The semiconductor light emitting device 3 is provided with a light emitting body 10 and a substrate 20. The light emitting body 10 is provided on the substrate 20. FIG. 10A is a top view illustrating a chip surface below the light emitting body 10. A dashed line in FIG. 10A illustrates the outer edge of the light emitting body 10.

As illustrated in FIG. 10A, the semiconductor light emitting device 3 is provided with an n-type electrode 33 and a p-type electrode 35 (a first metal layer) which are provided below the light emitting body 10. In the embodiment, the p-type electrode 35 includes a portion (an extending portion 35p) which extends to a location outside of the perimeter of the light emitting body 10, and a bonding pad 32 (a second metal layer) is provided on the extending portion 35p. A conductive layer 39 is provided between the bonding pad 32 and the extending portion 35p. The conductive layer 39 includes a first portion 39a which covers the extending portion 35p, and a second portion 39b which extends to an area between the light emitting body 10 and the p-type electrode 35.

The light emitting body 10 includes a plurality of recessed portions 55. The recessed portions 55 are arranged to be spaced from one another in, and are electrically isolated from, the p-type electrode 35. One n-type electrode 33 is provided in each of the recessed portions 55.

As illustrated in FIG. 10B, the light emitting body 10 is connected to the substrate 20 via the bonding layer 25, the p-type electrodes 35 and the insulating film 41, 45. The light emitting body 10 includes an n-type semiconductor layer 11, a p-type semiconductor layer 12, and a light emitting layer 15. The light emitting layer 15 is located between the n-type semiconductor layer 11 and the p-type semiconductor layer 12. The light emitting body 10 includes a first surface 10a including a surface of the n-type semiconductor layer 11, a second surface 10b including a surface of the p-type semiconductor layer 12 facing away from the first surface 10a, and a side surface 10c including an outer edge of the n-type semiconductor layer 11. The light extraction structure is preferably provided on the first surface 10a. A dielectric film 47 covers the first surface 10a and the side surface 10c. The recessed portions 55 extend inwardly of the light emitting portion 10, from the second surface 10b, to a location within the n-type semiconductor layer 11.

The n-type electrodes 33, the p-type electrode 35, and the dielectric films 41 and 45 are provided between the light emitting body 10 and the bonding layer 25. The dielectric film 41 covers an inner surface of the p-type semiconductor layer 12 and the inner surface of the recessed portion 55. The p-type electrode 35 contacts the surface of the p-type semiconductor layer 12 at openings in the dielectric film 41 where portions thereof were selectively removed. In addition, the n-type electrodes 33 contact the n-type semiconductor layer 11 at the base of the recessed portions 55. The dielectric film 45 covers the p-type electrode 35, the dielectric film 41, including that portion of the dielectric film 41 covering the wall of the inner surface of the recessed portion 55. The dielectric film 45 electrically insulates the p-type electrode 35 from the substrate 20 and the bonding layer 25. On the other hand, the bonding layer 25 extends into the recessed portion 55, and comes into contact with the n-type electrode 33. The n-type electrode 33 is electrically connected to the substrate 20 through the conductive bonding layer 25.

As illustrated in FIG. 10C, the p-type electrode 35 includes the extending portion 35p which extends on the dielectric film 45 over the bonding layer 25. The bonding pad 32 is provided on the conductive layer 39 on the extending portion 35p. The p-type electrode 35 is electrically connected to an external circuit by, for example, a metallic wire which is connected to the bonding pad 32.

The conductive layer 39 extends between the extending portion 35p and the dielectric film 41 to a location immediately below the light emitting body 10 and inwardly of the side surface 10c thereof. When the chip is viewed from above, a portion of the conductive layer 39 is overlapping with the light emitting body 10. In addition, when the chip surface is viewed from above, the outer edge of the conductive layer 39 is positioned between the outer edge of the light emitting body 10 and the contact portion 35c of the p-type electrode 35. Owing to this configuration, the conductive layer 39 effectively protects the p-type electrode 35, and improves the reliability of the semiconductor light emitting device 3.

In addition, in the embodiment, a term “nitride semiconductor” includes a semiconductor of all compositions in which the composition ratios x, y, and z are changed in the respective ranges in a chemical formula of BₓIn_{y}Al_{z}Ga_{1-x-y-z}N (0≦x≦1, 0≦y≦1, 0≦z≦1, x+y+z≦1). Further, in the aforementioned chemical formula, it is assumed that the term “nitride semiconductor” includes a material including group V elements in addition to N (nitrogen), a material further including various elements which are added so as to control various physical properties such as a conductivity type, and a material further including various elements which are unintentionally included.

In the above embodiment, when expressing the phrase “the portion A is provided on the portion B”, the preposition “on” may mean a case where the portion A is provided above the portion B while the portion A does not come into contact with the portion B in addition to a case where the portion A is provided on the portion B while the portion A comes into contact with the portion B. In addition, the phrase “the portion A is provided on the portion B” may be applied to a case where the portion A and the portion B are reversed and the portion A is positioned below the portion B or a case where the portion A and the portion B are disposed side by side. This is because that even when rotating the semiconductor device according to the embodiment, the structure of the semiconductor device is not changed before and after being rotated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed:

1. A semiconductor light emitting device comprising:
a light emitting body comprising a first semiconductor layer of a first conductivity type, a second semiconductor layer of a second conductivity type, and a light emitting layer provided between the first semiconductor layer and the second semiconductor layer;
a substrate located on the second semiconductor layer side of the light emitting body layer;
a first metal layer electrically connected to one of the first semiconductor layer and the second semiconductor layer at a location between the substrate and the light emitting body, including an extending portion extending over the substrate from a location between the substrate and the light emitting body to a location outside the perimeter of the light emitting body;
a conductive layer overlying the extending portion of the first metal layer extending to the location outside the perimeter of the light emitting body, and extending to a location between the light emitting body and the first metal layer; and
a second metal layer located adjacent to, and spaced from, the light emitting body on the substrate, and on a portion of the conductive layer overlying the extending portion, wherein
the light emitting body has a first surface comprising a surface of the first semiconductor layer, a second surface comprising a surface of the second semiconductor layer, and a side surface including an outer edge of the first semiconductor layer,
the light emitting body includes an opening extending inwardly from the side surface,
the second metal layer is located at least partially within the opening extending inwardly from the side surface, and
a side wall of the opening extending inwardly from the side surface connects to the side surface along a curved surface.

2. The device according to claim 1, wherein the curved surface has a radius of curvature equal to or greater than 0 μm to less than 30 μm.

3. The device according to claim 1, wherein
the light emitting body includes:
a light emitting portion that includes the light emitting layer, and
a non-light emitting portion that is provided in the vicinity of the light emitting portion adjacent a step from the second surface to the first semiconductor layer, and
the first metal layer is electrically connected to the first semiconductor layer in the non-light emitting portion.

4. The device according to claim 1, wherein
the light emitting body includes a recessed portion extending from the second surface to the first semiconductor layer,
the first semiconductor layer is electrically connected to the substrate through the recessed portion, and
the first metal layer is electrically connected to the second semiconductor layer on the second surface.

5. The device according to claim 1, wherein a gap between an outer edge of the light emitting body and the second metal layer is equal to or less than 50 μm.

6. The device according to claim 1, wherein the conductive layer comprises at least one metal having an etching resistance greater than the etching resistance of the first metal layer, a conductive metal oxide, and a conductive metal nitride.

7. The device according to claim 1, further comprising:
a dielectric film located between the light emitting body and a portion of the first metal layer which does not come into contact with the light emitting body, wherein
the dielectric film extends to a location outside the perimeter of the light emitting body along the conductive layer, and
the extending portion of the first metal layer does not contact a portion of the dielectric film extending outside of the perimeter of the light emitting body.

8. The device according to claim 1, further comprising a crack extending through the dielectric layer at a location thereof extending outwardly of the perimeter of the light emitting body.

9. The device according to claim 8, wherein the conductive layer is exposed to one end of the crack.

10. A light emitting device, comprising:
a light emitting body comprising a first semiconductor layer of a first conductivity type, a second semiconductor layer of a second conductivity type, and a light emitting layer provided between the first semiconductor layer and the second semiconductor layer;
a substrate located on the second semiconductor layer side of the light emitting body layer;
a first metal layer electrically connected to one of the first semiconductor layer and the second semiconductor layer at a location between the substrate and the light emitting body, including an extending portion extending over the substrate from a location between the substrate and the light emitting body to a location outside the perimeter of the light emitting body; and
a second metal layer located adjacent to, and spaced from, the light emitting body on the substrate, and on a portion of a conductive layer overlying the extending portion, wherein
the light emitting body has a first surface comprising a surface of the first semiconductor layer, a second surface comprising a surface of the second semiconductor layer, and a side surface including an outer edge of the first semiconductor layer, and
an outer edge of the light emitting body comprises at least one corner having a radius of curvature of greater than 0 μm and less than 30 μm.

11. The device according to claim 10, wherein
the light emitting body includes an opening extending inwardly from the side surface,
the second metal layer is located at least partially within the opening,
a side wall of the opening connects to the side surface along a curved surface, and
the curved surface has a radius of curvature equal to or greater than 0 μm and less than 30 μm.

12. The device according to claim 10, wherein
the light emitting body includes:
a light emitting portion that includes the light emitting layer, and
a non-light emitting portion that is provided in the vicinity of the light emitting portion adjacent a step from the second surface to the first semiconductor layer, and
the first metal layer is electrically connected to the first semiconductor layer in the non-light emitting portion.

13. The device according to claim 11, wherein
the light emitting body includes a recessed portion extending from the second surface to the first semiconductor layer,
the first semiconductor layer is electrically connected to the substrate through the recessed portion, and
the first metal layer is electrically connected to the second semiconductor layer on the second surface.

14. The device according to claim 10, wherein a gap between an outer edge of the light emitting body and the second metal layer is equal to or less than 50 μm.

15. A light emitting device, comprising:
a light emitting body having a perimeter located over a substrate;
a first metal layer electrically connected to the light emitting body, the first metal layer comprising a first portion contacting the light emitting body and a second portion spaced from the light emitting body and the substrate, and extending to a location located outwardly of the perimeter of the light emitting body; and
a dielectric layer extending between a the second portion of the first metal layer and the light emitting body, the dielectric layer extending from the location between second portion of the first metal layer and the light emitting body to a location located outwardly of perimeter of the light emitting body, and a conductive layer, disposed between a portion of the dielectric layer and the second portion, the conductive layer being more resistant to an etchant used to etch the light emitting body than the resistance of the first metal layer to an etchant used to etch the light emitting body.

16. The device according to claim 15, wherein the conductive layer extends on the first metal layer to a location further from the perimeter of the light emitting body than the location of the terminus of the dielectric layer outwardly of the light emitting body; and
an electrode is disposed on the portion of the first metal layer extending further from the perimeter of the light emitting body than the terminus of the dielectric layer outwardly of the light emitting body.

17. The device according to claim 15, further comprising:
a crack extending through the dielectric layer in a portion thereof located outwardly of the perimeter of the light emitting body.

18. The device according to claim 15, wherein the perimeter of the light emitting body comprises at least one corner, and the corner has a radius of curvature of greater than 0 μm to less than 30 μm.

19. The device according to claim 15, wherein the light emitting body includes a light emitting portion and a non-light emitting portion surrounding the light emitting portion.
